(19) United States
(12) Patent Application Publication
(10) Pub. No.: US 2023/0317551 A1
(43) Pub. Date: Oct. 5, 2023

(54) HETEROGENEOUS PACKAGES HAVING THERMAL TOWERS

(71) Applicant: Intel Corporation, Santa Clara, CA (US)

(72) Inventors: Vishnu Prasad, Muenchen (DE); Abdallah Bacha, Munich (DE); Mohan Prashanth Javare Gowda, Ottobrunn (DE); Lizabeth Keser, San Diego, CA (US); Thomas Wagner, Regelsbach (DE); Bernd Waidhas, Pettendorf (DE); Sonja Koller, Lappersdorf (DE); Eduardo De Mesa, Munich (DE); Jan Proschwitz, Riesa (DE)

(21) Appl. No.: 17/708,890

(22) Filed: Mar. 30, 2022

(51) Int. Cl. H01L 23/373; H01L 25/18; H01L 21/48

(52) U.S. Cl. CPC H01L 23/3736; H01L 25/18; H01L 21/4896

(57) ABSTRACT

Disclosed herein are microelectronics packages that include thermal pillars for at least localized extraction of generated heat and methods for manufacturing the same. The microelectronics packages may include a substrate and a plurality of dies stacked on the substrate with at least one of the plurality of dies connected to the substrate. A heat spreader may be located proximate at least a portion of the plurality of dies. Respective thermal pillars from a plurality of thermal pillars may extend from at least one of the plurality dies to the heat spreader. Each of the plurality of thermal pillars may define a respective pathway from at least one of the plurality of dies to the heat spreader.

### FIELD OF THE DISCLOSURE

The present subject matter relates to microelectronics packages. More specifically, the present disclosure relates to thermal pillar towers used in microelectronics package applications to achieve high thermal power dissipation.

### BACKGROUND

Complex advanced two-dimensional and three-dimensional stacked dies in a microelectronics package are facing performance limitations due to high thermal resistive paths. During operations, the heat generated by the microelectronics package flows through all the dies before it reaches a heat sink, generating a temperature drop across the stack. Disclosed herein are solutions for extracting the generated heat to improve the thermal power dissipation.

### BRIEF DESCRIPTION OF THE FIGURES

In the drawings, which are not necessarily drawn to scale, like numerals may describe similar components in different views. Like numerals having different letter suffixes may represent different instances of similar components. The drawings illustrate generally, by way of example, but not by way of limitation, various embodiments discussed in the present document.

FIG. 1A shows a microelectronics package in accordance with at least one example of this disclosure.

FIG. 1B shows a detail of a microelectronics package in accordance with at least one example of this disclosure.

FIG. 1C shows a cross-section of a microelectronics package in accordance with at least one example of this disclosure.

FIG. 1D shows a detail of a microelectronics package in accordance with at least one example of this disclosure.

FIG. 1E shows a detail of a microelectronics package in accordance with at least one example of this disclosure.

FIG. 1F shows a cross-section of a microelectronics package in accordance with at least one example of this disclosure.

FIG. 1G shows a detail of a microelectronics package in accordance with at least one example of this disclosure.

FIG. 2 shows a process for exposing a metal plate of a microelectronics package in accordance with at least one example of this disclosure.

FIG. 3 show a method for manufacturing a microelectronics package in accordance with at least one example of this disclosure.

FIGS. 4A and 4B show temperature maps in accordance with at least one example of this disclosure.

FIG. 5 shows system level diagram in accordance with at least one example of this disclosure.

### DETAILED DESCRIPTION

Solutions to extract heat disclosed herein can include the used integrated heat spreaders, thermal lids, thermal interface materials, etc. that may be couple with thermal towers, sometimes referred to as thermal pillars and/or thermal pillar towers.

The systems and methods disclosed herein may provide the ability to isolate and extract heat from individual dies, chiplets, etc. As disclosed herein, the term die may include, but is not limited to, an die having bumps, balls, or other electrical interconnects, and/or a package of stacked dies. Thus, the systems and methods disclosed herein may allow for heat to be extracted from individual components thereby helping to minimize the heating up of subsequent chips before the heat reaches a cooling solution.

As disclosed herein, localized and targeted thermal towers may be strategically placed in a package to isolate and extract heat from each layer of a multilayered package. The thermal towers described herein may be placed next to hotspots and/or in between chiplets. The individual stacks may be connected to these thermal towers through conformal shielding. The thermal towers may then be connected to additional cooling components and/or solutions, such as thermal lids, heat spreaders, thermal interface materials, etc.

As disclosed herein, a microelectronics package may include a substrate, a first die, a second die, and a third die. The second die may be located above and/or connected to the first die. The third die may be located above and/or connected to the first die and/or the second die. A thermal tower may extend from a surface of the first die to a heat spreader and may be located in between the second and third dies to define a conductive pathway from the first die to the heat spreader. The microelectronics packages disclosed herein may further include a second thermal tower that may thermally couple the second die to the heat spreader and a third thermal tower may thermally couple the third die to the heat spreader. Stated another way, a plurality of thermal towers may be used to thermally couple various dies to cooling solutions thereby providing thermal pathways for heat that is locally generated to be extracted without flowing through adjacent dies.

The microelectronics packages disclosed herein may further include a metal plate attached to a surface of a die. The thermal towers may thermally connect the metal plate to a heat spreader or other thermal solution. A sputtered conformal layer may contact the metal plate. The metal plate may define a plurality of through holes sized to allow one or more bumps and thermal towers to pass though the metal plate. The bumps may electrically couple the various dies. Thus, the bumps may electrically couple dies and form electrical pathways through the dies while the thermal towers do not form an electrical pathway through the microelectronics package.

The above discussion is intended to provide an overview of subject matter of the present patent application. It is not intended to provide an exclusive or exhaustive explanation. The description below is included to provide further information.

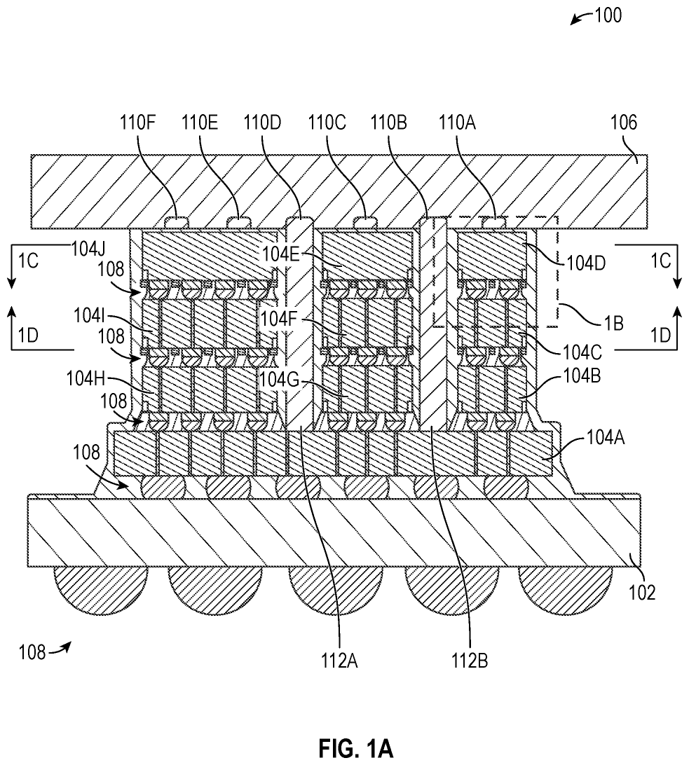

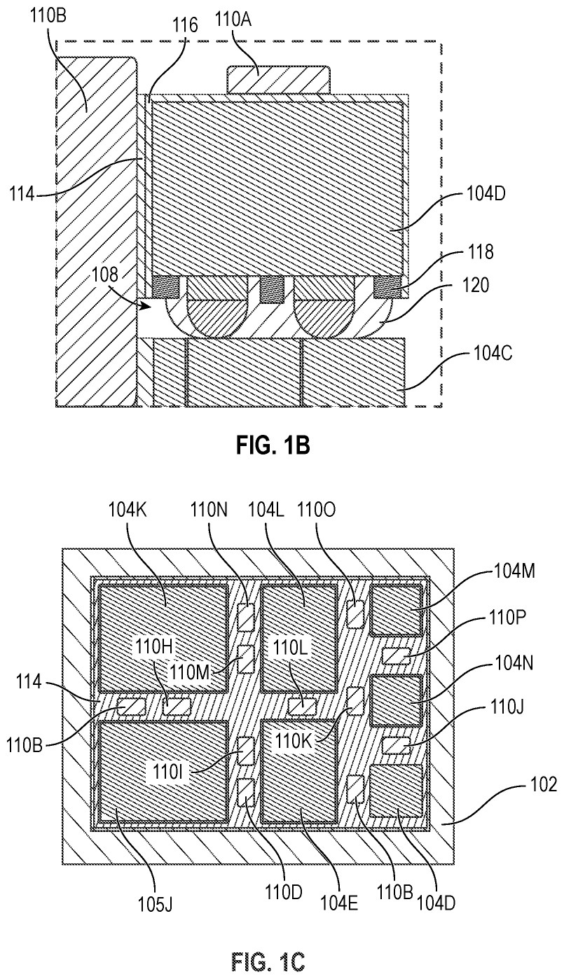

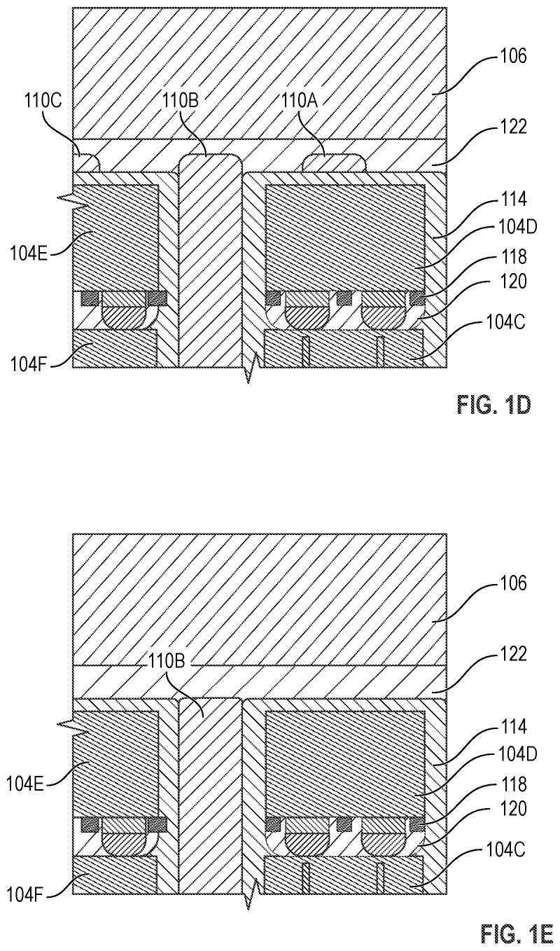

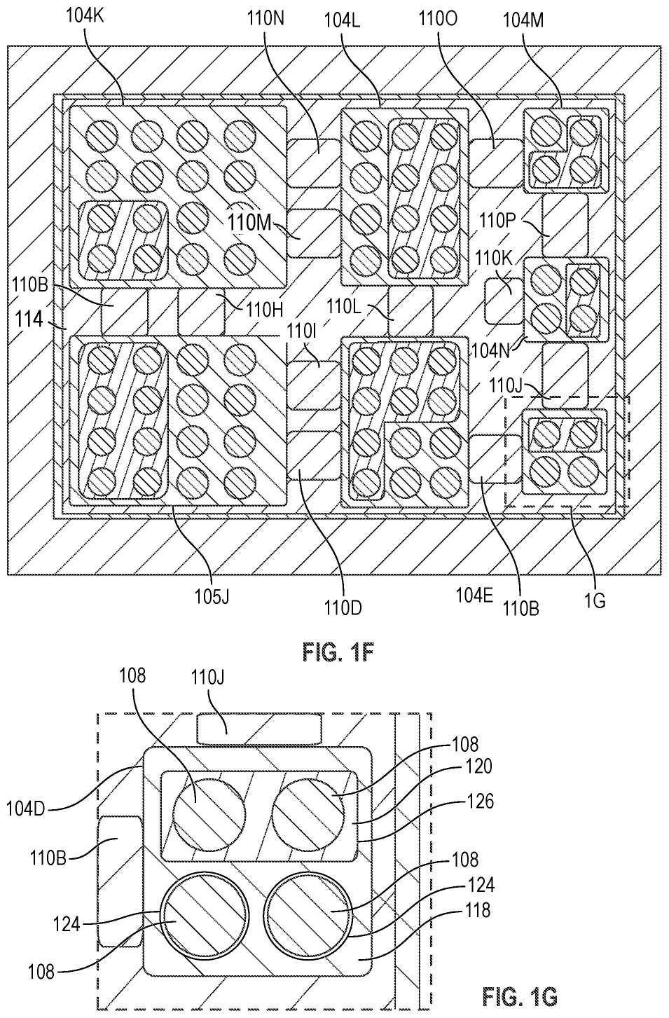

Turning now to the figures, FIG. 1A shows a microelectronics package 100 in accordance with at least one example of this disclosure. FIG. 1B shows a detail of microelectronics package 100 in accordance with at least one example of this disclosure. FIGS. 1C and 1D each shows a cross section of microelectronics package 100 in accordance with at least one example of this disclosure.

Microelectronics package 100 may include a substrate 102, a plurality of dies 104 (labeled individually as dies 104A, 104B, . . . 104N), and a heat spreader 106. Plurality of dies 104 may be a combination of dies (memory and/or compute dies), chiplets, system on chips (SOCs), etc. Various dies of plurality of dies 104 may be electrically coupled to substrate 102 and/or other dies of plurality of dies 104 via bumps 108. During operation, plurality of dies 104 generate heat. This heat may cause warpage, delamination, and/or other structure deformation of microelectronics package 100. The deformation and heat may cause performance degradation as well as failure of microelectronics package 100. For example, increases in heat within microelectronics package 100 may increase leakage currents and thus power consumption of dies, which in turn can further increase the heat. This increase in heat can lead to throttling or shutdown of microelectronics package 100 and/or system failure.

The heat buildup and associated temperature rise may be cause by an inability to isolate and extract heat from individual dies and/or chiplets. The buildup of heat may heat neighboring dies in an attempt to escape from microelectronics package 100. The result may be the heating up of subsequent dies before the heat reaches a cooling solution. Heat flowing through silicon vias (TSVs) may also heat other portions of microelectronics package 100 such as other dies. In addition, TSVs are not sufficient to extract the heat generated.

To combat the buildup of heat, thermal towers 110 (labeled individually as thermal towers 110A, 110B, 110C, . . . 110P) may be disbursed throughout microelectronics package 100. In some embodiments, thermal towers 110 may comprise metal structures form of, for example, thermally conductive metals such as copper. Thermal towers 110 may be disbursed such that they connect hotspots of respective dies to heat spreader 106. As shown in FIG. 1A, a subset of thermal tower 110, e.g., towers 110B and 110D may connect a first die, e.g., die 104A, which may be connected to substrate 102, to heat spreader 106. The locations of towers 110B and 110D, as well as other towers may be such that a first end 112A and 112B of towers 110B and 110D are connected to, or otherwise located proximate, hotspots of die 104A.

As shown in FIG. 1B, a thermal interface material 114 may be used to thermally couple dies to thermal towers 110. For example, thermal interface material 114 may be used to thermally couple sides, and/or top and bottom surfaces of any or all of plurality of dies 104 to an adjacent one or more of thermal towers 110. By connecting available surfaces of plurality of dies 104 to nearby thermal towers 110, thermal towers 110 may define and/or otherwise form thermal pathways for heat generated by respective plurality of dies 104 to escape to heat spreader 106 and/or other heat extraction solutions.

Stated another way, thermal towers may be localized and targeted thermal pillars that may be strategically placed in microelectronics package 100 to isolate and extract heat from each layer of a multilayered package. As disclosed herein, thermal towers 100 may be placed next to hot-spots and/or in between chiplets, dies, etc. The individual stacks may be connected to thermal towers through conformal shielding and/or through thermal interface material 114. As described herein, a thermal pillar may comprise a thermally conductive material such as a metal (e.g., copper) that conducts thermal energy from one portion, structure or region of a semiconductor package (e.g., a die hot spot region) to another portion, structure or region of the package (e.g., a heat spreader).

As a result of the strategic placement of thermal towers, localized heat extraction and prevention of otherwise subsequent heating up of neighboring chips may be achieved. As disclosed herein, potential hotspots within microelectronics package 100 may be determined via simulations. For example, solid models of microelectronics package 100 may be generated and finite element analysis performed to identify potential hotspots and/or other areas of heat buildup. Upon identifying potential hotspots, one or more thermal towers may be placed so as to increase the conduction or transfer of heat away from the identified areas of heat buildup. The total thermal power dissipation may increase due to the presents of thermal towers 100, resulting in higher power & performance capability.

As disclosed herein, thermal bottlenecks may be a major challenge to increase performance in heterogeneous packages. The placement of thermal pillars 110 may solve this issue by providing for localized heat extraction at individual levels of the stacked package. For example, thermal pillars 110 may allow for localized heat extraction at various levels of the stacked dies (i.e., plurality of dies 104) that form microelectronics package 100.

As disclosed herein, thermal pillars 100 may be strategically placed between the dies 104. The location of these pillars may be carefully selected to eliminate hotspots in the package and minimize heating of neighboring dies. Also, decisive may be to place pillars between segregated die stacks to maximize heat extraction.

As shown in FIG. 1B, a conformal layer 116 may thermally couple any one of or all of dies 104 to a thermal pillar, such as thermal pillar 110B as shown in FIG. 1B. Conformal layer 116 may be generated by the process of sputtering on individual die stacks. Plating and sputtering may result in detectable physical characteristics including, but not limited to, metal grain orientation and size. Once the conformal layer 116, which may be a conformal metal layer, is in place, galvanic plating may be used to fill any gaps with copper or similar high conductive material to create thermal pillars.

As further shown in FIG. 1B, a metal plate 118, sometimes called a metal layer, may be formed on an underside of one or more of dies 104, such as die 104D as shown in FIG. 1B. Metal plate 118 may be formed with a plurality of through holes that allow bumps 108 to pass through metal plate 118. By passing through metal plate 118, bumps 108 may electrically couple various dies together, such as die 104D to die 104C. Metal plate 118 may be covered by underfill 120, but partially exposed through the use of plasma etching as disclosed herein.

As shown in FIG. 1D, a thermal interface material 122 may be wrapped around thermal pillars 110. Thermal interface material 122 may improve, or otherwise lower contact resistance between thermal pillars 110 and heat spreader 106. In addition, and as shown in FIG. 1D, thermal interface material 122 may be used to compensate for any unevenness that may result from thermal pillars 104 protruding above a top surface of a die stack. As shown in FIG. 1E, the tops of thermal pillars 104 may be ground down to be flush with a top surface of die stacks and thermal interface material 122 may be applied to bond heat spreader 106 to thermal pillars 110 and one or more of dies 104.

As disclosed herein, metal plate 118 may be used to thermally couple portions of dies 104 to thermal pillars 110. As shown in FIG. 1F, which show a section through metal plate 118, metal plate 118 may define through holes 124 through which bumps 108 may pass. In addition to individual through holes, metal plate 118 may define openings, such as opening 126, to allow multiple bumps to pass through metal plate 118.

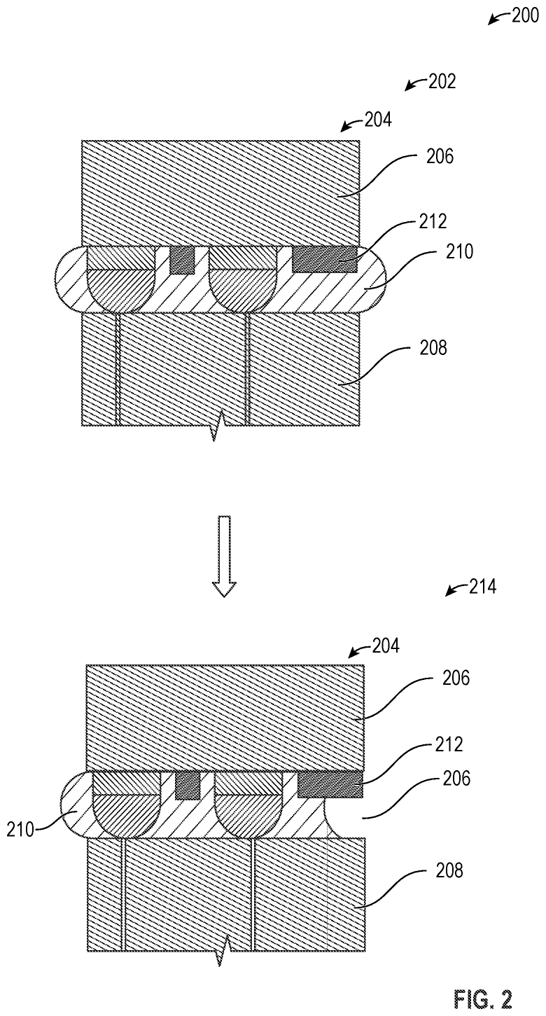

FIG. 2 shows a process 200 for exposing metal plate 118 of microelectronics package 100 in accordance with at least one example of this disclosure. At stage 202, a die stack 204 has a first die 206 bonded to a second die 208 via an underfill material 210. As shown in stage 202, portions of underfill material 210 may protrude past a parameter of dies 206 and 208. In addition, underfill material 210 may prevent a metal plate 212 from contacting a thermal pillar as disclosed herein.

Excess underfill material may be removed to expose metal plate 212 in stage 214. The excess underfill material may be removed by via plasma processes, etching processes, lithography, etc. For example, the excessive underfill material may be plasma cleaned to expose all or a portion of metal plate 212 as shown in FIG. 2.

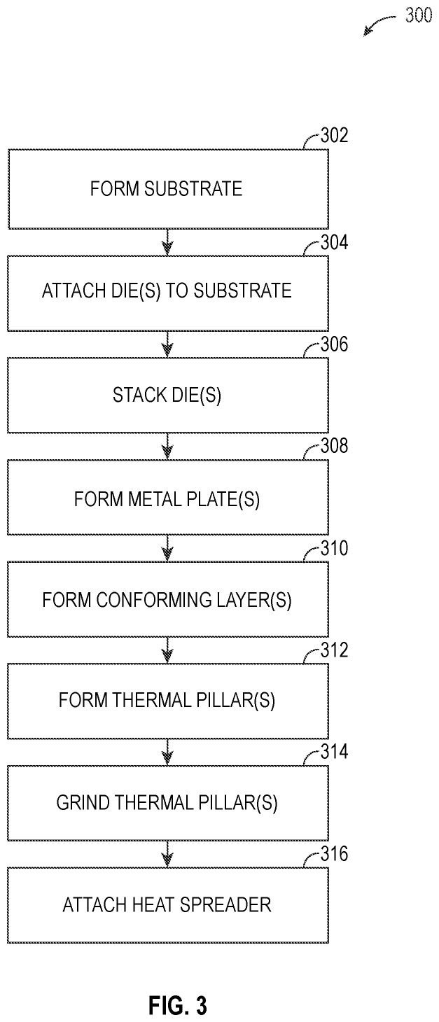

FIG. 3 show a method 300 for manufacturing a microelectronics package having thermal pillars in accordance with at least one example of this disclosure. Method 300 may begin at stage 302 where a substrate may be formed. The substrate may be formed on a printed circuit board (PCB), a carrier (e.g., a glass carrier), etc. and may have a substrate surface.

Once the substrate is formed, one or more dies, such a first die, may be attached to the substrate surface (304). A plurality of dies may then be stacked on the die(s) attached to the substrate (306).

One or more metal plates may be formed on one more sides, such as bottom and/or topsides, of the various dies (308). The metal plates may be formed before the various dies are stacked or formed while the dies are stacked. For example, the metal plates may be formed on the various dies prior to stacking the dies. Still consistent with embodiments disclosed herein, as each layer of dies are place upon the stack the metal plates may be formed. Forming the metal plates may include forming one or more through holes to accommodate various bumps individually and/or forming larger through holes to accommodate two or more bumps.

One or more conformal layer may be formed (310). For example, conformal layers may be formed to provide better surface contact between dies and thermal pillars as disclosed herein. The conformal layers may be coated with a metal or other thermal interface materials to improve heat transfer from the microelectronics package to the thermal towers as disclosed herein.

A plurality of thermal pillars may be formed (312). As disclosed herein, each of the thermal pillars may thermally couple at least one of the dies to a heat spreader. As disclosed herein, the thermal pillars may be formed of copper or other materials with a high thermal conductivity. The high thermal conductivity may allow the thermal pillars to form one or more thermally conductive pathways from a hotspot of a respective die to the heat spreader or other solution to remove heat from the die stack.

Once the thermal pillars are formed the ends of thermal pillars may be ground flush with a top surface of the various dies adjacent to the heat spreader (314). As disclosed herein, grinding the ends of the thermal pillars may allow for more surface area of the heat spreader to contact both the thermal pillars and top surfaces of dies located at the top of the die stack.

A heat spreader, heat sink, and/or other cooling solutions may be attached to the top of the die stack (316). Attaching the heat spreader to the die stack may include applying a thermal interface material to portions of the heat spreader and/or die stack to lower a thermal contact resistance.

The various stages of method 300 may be performed in various orders and/or stages may be removed without departing from the scope of this disclosure. For example, as disclosed herein, the ends of the thermal pillars need not be ground flat and the thermal interface material may be used to fill gaps and/or otherwise compensate for surface irregularities that may exist. In addition, stages may be added to method 300 without departing from the scope of this disclosure. For example, a finite element analysis of the die stack may be performed prior to manufacturing the die stack to identify hotspots. Once the potential hotspots are identified, thermal pillars may be incorporated into the design and a second iteration of finite element analysis may be performed to determine potential effects the thermal pillars may have on cooling the die stack.

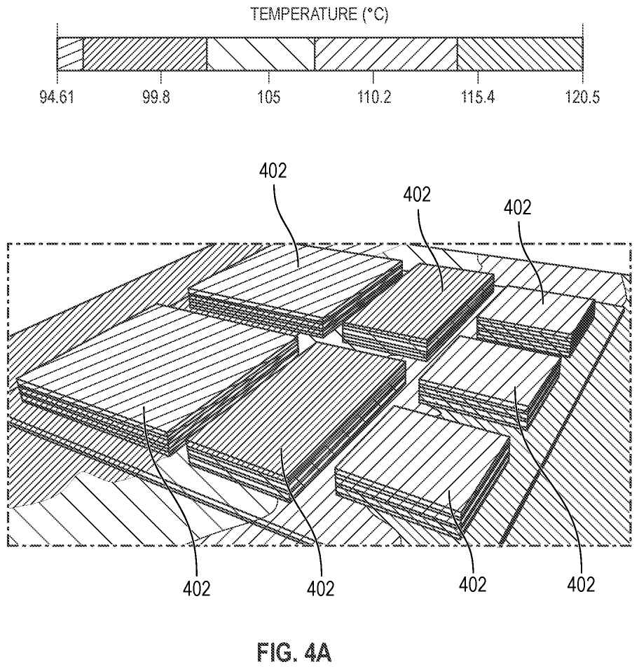

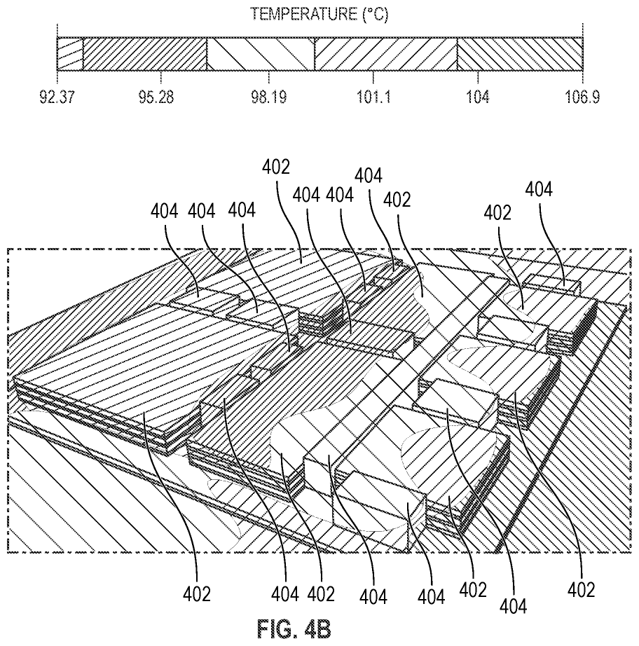

For example, FIG. 4A shows a temperature map that may be developed using finite element analysis, CFD simulation tools, or other numerical techniques for a microelectronics package that does not include thermal pillars. As shown in FIG. 4A, the temperatures may range from about 94.5° C. to about 120.5° C. FIG. 4B shows a temperature map that may be developed using finite element analysis, CFD simulation tools, or other numerical techniques for the microelectronics package having strategically place thermal pillars as disclosed herein. As shown in FIG. 4B, the temperatures may range from about 94.3° C. to about 107.0° C. For the high temperatures, this equates to an over 11% drop in operating temperatures, which represents a significant improvement in operating temperatures.

In the examples shown in FIGS. 4A and 4B, the model emulates a heterogeneous package with several stacked-on dies 402 and high-power dissipation of approximately 50 W. The package is assumed to be cooled from the top using a heat-sink or other cooling solutions.

In the example package, the placement of thermal pillars 404 is expected to give approximately 15° C. advantage over the package without thermal pillars 404. In a real product with more complex power map on the dies, strategic placing, and sizing of thermal pillars together with a tuned choice of materials is expected to give further advantages to two-dimensional and three-dimensional die stack packages.

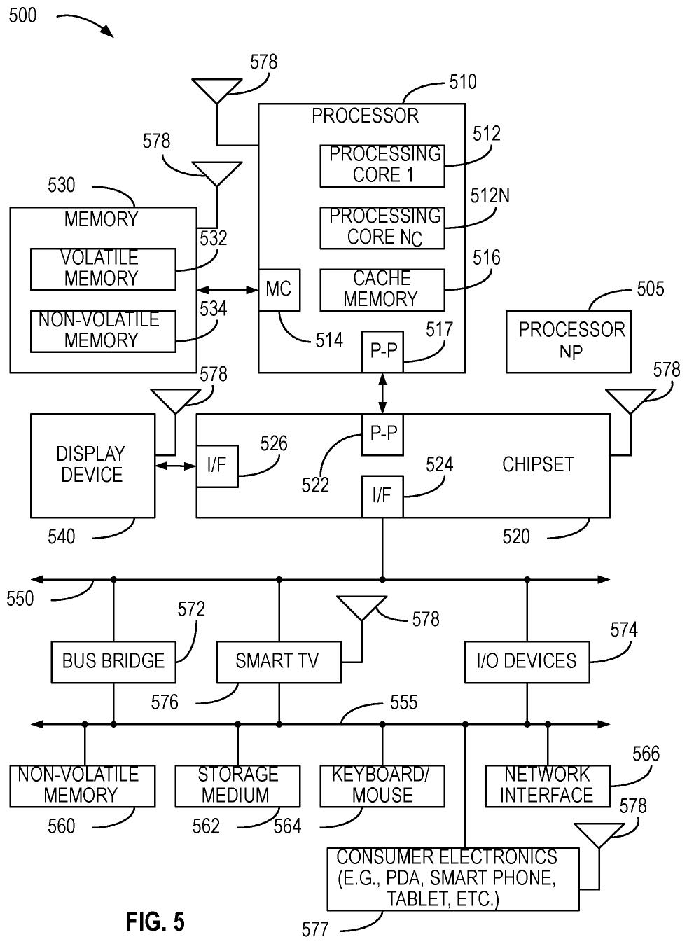

FIG. 5 illustrates a system level diagram, according to one embodiment of the invention. For instance, FIG. 5 depicts an example of an electronic device (e.g., system) including microelectronics package 100 as described herein. FIG. 5 is included to show an example of a higher level device application for the present invention. In one embodiment, system 500 includes, but is not limited to, a desktop computer, a laptop computer, a netbook, a tablet, a notebook computer, a personal digital assistant (PDA), a server, a workstation, a cellular telephone, a mobile computing device, a smart phone, an Internet appliance or any other type of computing device. In some embodiments, system 500 is a system on a chip (SOC) system.

In one embodiment, processor 510 has one or more processing cores 512 and 512N, where 512N represents the Nth processor core inside processor 510 where N is a positive integer. In one embodiment, system 500 includes multiple processors including 510 and 505, where processor 505 has logic similar or identical to the logic of processor 510. In some embodiments, processing core 512 includes, but is not limited to, pre-fetch logic to fetch instructions, decode logic to decode the instructions, execution logic to execute instructions and the like. In some embodiments, processor 510 has a cache memory 516 to cache instructions and/or data for system 500. Cache memory 516 may be organized into a hierarchal structure including one or more levels of cache memory.

In some embodiments, processor 510 includes a memory controller 514, which is operable to perform functions that enable the processor 510 to access and communicate with memory 530 that includes a volatile memory 532 and/or a non-volatile memory 534. In some embodiments, processor 510 is coupled with memory 530 and chipset 520. Processor 510 may also be coupled to a wireless antenna 578 to communicate with any device configured to transmit and/or receive wireless signals. In one embodiment, the wireless antenna interface 578 operates in accordance with, but is not limited to, the IEEE 802.11 standard and its related family, Home Plug AV (HPAV), Ultra Wide Band (UWB), Bluetooth, WiMax, or any form of wireless communication protocol.

In some embodiments, volatile memory 532 includes, but is not limited to, Synchronous Dynamic Random Access Memory (SDRAM), Dynamic Random Access Memory (DRAM), RAMBUS Dynamic Random Access Memory (RDRAM), and/or any other type of random access memory device. Non-volatile memory 534 includes, but is not limited to, flash memory, phase change memory (PCM), read-only memory (ROM), electrically erasable programmable read-only memory (EEPROM), or any other type of non-volatile memory device.

Memory 530 stores information and instructions to be executed by processor 510. In one embodiment, memory 530 may also store temporary variables or other intermediate information while processor 510 is executing instructions. In the illustrated embodiment, chipset 520 connects with processor 510 via Point-to-Point (PtP or P-P) interfaces 517 and 522. Chipset 520 enables processor 510 to connect to other elements in system 500. In some embodiments of the invention, interfaces 517 and 522 operate in accordance with a PtP communication protocol such as the Intel® QuickPath Interconnect (QPI) or the like. In other embodiments, a different interconnect may be used.

In some embodiments, chipset 520 is operable to communicate with processor 510, 505N, display device 540, and other devices 572, 576, 574, 560, 562, 564, 566, 577, etc. Chipset 520 may also be coupled to a wireless antenna 578 to communicate with any device configured to transmit and/or receive wireless signals.

Chipset 520 connects to display device 540 via interface 526. Display 540 may be, for example, a liquid crystal display (LCD), a plasma display, cathode ray tube (CRT) display, or any other form of visual display device. In some embodiments of the invention, processor 510 and chipset 520 are merged into a single SOC. In addition, chipset 520 connects to one or more buses 550 and 555 that interconnect various elements 574, 560, 562, 564, and 566. Buses 550 and 555 may be interconnected together via a bus bridge 572. In one embodiment, chipset 520 couples with a non-volatile memory 560, a mass storage device(s) 562, a keyboard/mouse 564, and a network interface 566 via interface 524 and/or 504, smart TV 576, consumer electronics 577, etc.

In one embodiment, mass storage device 562 includes, but is not limited to, a solid state drive, a hard disk drive, a universal serial bus flash memory drive, or any other form of computer data storage medium. In one embodiment, network interface 566 is implemented by any type of well known network interface standard including, but not limited to, an Ethernet interface, a universal serial bus (USB) interface, a Peripheral Component Interconnect (PCI) Express interface, a wireless interface and/or any other suitable type of interface. In one embodiment, the wireless interface operates in accordance with, but is not limited to, the IEEE 802.11 standard and its related family, Home Plug AV (HPAV), Ultra Wide Band (UWB), Bluetooth, WiMax, or any form of wireless communication protocol.

While the modules shown in FIG. 5 are depicted as separate blocks within the system 500, the functions performed by some of these blocks may be integrated within a single semiconductor circuit or may be implemented using two or more separate integrated circuits. For example, although cache memory 516 is depicted as a separate block within processor 510, cache memory 516 (or selected aspects of 516) can be incorporated into processor core 512.

### Additional Notes

The following, non-limiting examples, detail certain aspects of the present subject matter to solve the challenges and provide the benefits discussed herein, among others.

Example 1 is a microelectronics package comprising: a substrate; a first die connected to the substrate; a second die located above the first die; a third die located above the first die; a heat spreader located above the second and third dies; and a first metal pillar extending from a first surface of the first die to the heat spreader, the first metal pillar located in between the second and third dies.

In Example 2, the subject matter of Example 1 optionally includes a second metal pillar extending from the second die to the heat spreader.

In Example 3, the subject matter of Example 2 optionally includes a third metal pillar extending from the third die to the heat spreader.

In Example 4, the subject matter of any one or more of Examples 1-3 optionally include a metal plate attached to a surface of the first die, the first metal pillar thermally connecting the metal plate to the heat spreader.

In Example 5, the subject matter of Example 4 optionally includes a conformal metal layer on at least one of the first, second, or third die, the conformal metal layer located between first metal pillar and the at least one of the first, second, or third die.

In Example 6, the subject matter of any one or more of Examples 1-5 optionally include a thermal interface material located in between the first metal pillar and at least one of the first and second dies.

In Example 7, the subject matter of any one or more of Examples 4-6 optionally include wherein the metal plate defines a plurality of through holes sized to allow one or more bumps to pass though the metal plate.

In Example 8, the subject matter of any one or more of Examples 1-7 optionally include wherein the first metal pillar defines a second conductive pathway from at least one of the second and third dies to the heat spreader.

In Example 9, the subject matter of any one or more of Examples 1-8 optionally include wherein the first metal pillar comprising copper.

In Example 10, the subject matter of any one or more of Examples 1-9 optionally include wherein the first metal pillar does not form an electrical pathway through the microelectronics package.

Example 11 is a microelectronics package comprising: a substrate; a first die connected to the substrate; a second die located above the first die; a third die located above the first die; a heat spreader located above the second and third dies; and a first thermal pillar extending from a first surface of the first die to the heat spreader, the first thermal pillar located in between the second and third dies to define a thermally conductive pathway from the first die to the heat spreader.

In Example 12, the subject matter of any one or more of Examples 1-11 optionally include a second thermal pillar thermally coupling the second die to the heat spreader.

In Example 13, the subject matter of any one or more of Examples 2-12 optionally include a third thermal pillar thermally coupling the third die to the heat spreader.

In Example 14, the subject matter of any one or more of Examples 1-13 optionally include a metal plate attached to a surface of the first die, the first thermal pillar thermally connecting the metal plate to the heat spreader.

In Example 15, the subject matter of any one or more of Examples 4-14 optionally include a sputtered conformal layer that is at least one of a sputter and a plated metal layer.

In Example 16, the subject matter of any one or more of Examples 1-15 optionally include a thermal interface material located in between the first thermal pillar and at least one of the first and second dies.

In Example 17, the subject matter of any one or more of Examples 4-16 optionally include wherein the metal plate defines a plurality of through holes sized to allow one or more bumps to pass though the metal plate.

In Example 18, the subject matter of any one or more of Examples 1-17 optionally include wherein the first thermal pillar defines a second conductive pathway from at least one of the second and third dies to the heat spreader.

In Example 19, the subject matter of any one or more of Examples 1-18 optionally include wherein a first end of the first thermal pillar is located proximate a hotspot of the first die.

In Example 20, the subject matter of any one or more of Examples 1-19 optionally include wherein the first thermal pillar does not form an electrical pathway through the microelectronics package.

Example 21 is a microelectronics package comprising: a substrate; a plurality of dies stacked on the substrate; a heat spreader located proximate at least a portion of the plurality of dies; and a plurality of thermal pillars, respective ones of the plurality of thermal pillars extending from at least one of the plurality dies to the heat spreader, each of the plurality of thermal pillars defining a respective pathway from at least one of the plurality of dies to the heat spreader.

In Example 22, the subject matter of Example 21 optionally includes wherein at least one of the plurality of thermal pillars connects at least two of the plurality of dies to the heat spreader.

In Example 23, the subject matter of any one or more of Examples 21-22 optionally include a plurality of metal planes, each of the plurality of metal planes attached to a surface of at least one of the plurality of dies, at least a portion of the thermal pillars thermally connecting the plurality of metal planes to the heat spreader.

In Example 24, the subject matter of Example 23 optionally includes at least one sputtered conformal layer that is at least one of a sputter and plated metal layer.

In Example 25, the subject matter of any one or more of Examples 21-24 optionally include a thermal interface material located in between the first thermal pillar and at least one of the first and second dies.

In Example 26, the subject matter of any one or more of Examples 23-25 optionally include wherein each of the plurality of metal layer defines a plurality of through holes sized to allow one or more bumps and the first thermal pillar to pass though the metal layer.

In Example 27, the subject matter of any one or more of Examples 21-26 optionally include wherein a first end of at least a portion of the plurality of thermal pillars is located proximate a hotspot of a respective one of the plurality of dies.

In Example 28, the subject matter of any one or more of Examples 21-27 optionally include wherein the plurality of thermal pillars does not form electrical pathways through the microelectronics package.

Example 29 is a microelectronics package comprising: a substrate; a plurality of dies stacked on the substrate; a heat spreader located proximate at least a portion of the plurality of dies; and a plurality of metal pillars, respective ones of the plurality of metal pillars extending from at least one of the plurality dies to the heat spreader, each of the plurality of metal pillars defining a respective pathway from at least one of the plurality of dies to the heat spreader.

In Example 30, the subject matter of Example 29 optionally includes wherein at least one of the plurality of metal pillars connects at least two of the plurality of dies to the heat spreader.

In Example 31, the subject matter of any one or more of Examples 29-30 optionally include a plurality of metal plates, each of the plurality of metal plates attached to a surface of at least one of the plurality of dies, at least a portion of the metal pillars thermally connecting the plurality of metal plates to the heat spreader.

In Example 32, the subject matter of Example 31 optionally includes at least one sputtered conformal layer that is at least one of a sputter and plated metal layer.

In Example 33, the subject matter of any one or more of Examples 29-32 optionally include a thermal interface material located in between the first metal pillar and at least one of the first and second dies.

In Example 34, the subject matter of any one or more of Examples 31-33 optionally include wherein each of the plurality of metal layer defines a plurality of through holes sized to allow one or more bumps and the first metal pillar to pass though the metal layer.

In Example 35, the subject matter of any one or more of Examples 29-34 optionally include wherein a first end of at least a portion of the plurality of metal pillars is located proximate a hotspot of a respective one of the plurality of dies.

In Example 36, the subject matter of any one or more of Examples 29-35 optionally include wherein the plurality of metal pillars does not form electrical pathways through the microelectronics package.

Example 37 is a method of manufacturing a microelectronics package, the method comprising: forming a substrate layer having a substrate surface; attaching a first die to the substrate surface; stacking a plurality of dies to the first die; and forming a plurality of thermal pillars, each of the plurality of thermal pillars thermally coupling at least one of the first die or one of the plurality of dies to a heat spreader.

In Example 38, the subject matter of Example 37 optionally includes grinding a first end of at least a portion of the plurality of thermal pillars.

In Example 39, the subject matter of any one or more of Examples 37-38 optionally include attaching the heat spreader to the first end of the at least a portion of the plurality of thermal pillars.

In Example 40, the subject matter of any one or more of Examples 37-39 optionally include attaching the heat spreader to the first of the plurality of thermal pillars.

In Example 41, the subject matter of any one or more of Examples 37-40 optionally include forming at least one metal plane in between at least two of the plurality of dies during stacking the plurality of dies.

In Example 42, the subject matter of Example 41 optionally includes forming a conformal layer in between at least two of the plurality of dies during stacking the plurality of dies.

In Example 43, the subject matter of any one or more of Examples 37-42 optionally include wherein forming the plurality of thermal pillars comprises forming a forming a first end of at least one of the plurality of thermal pillars proximate a hotspot of a respective one of the plurality of dies or the first die.

Example 44 is a method of manufacturing a microelectronics package, the method comprising: forming a substrate layer having a substrate surface; attaching a first die to the substrate surface; stacking a plurality of dies to the first die; and forming a plurality of metal pillars, each of the plurality of metal pillars thermally coupling at least one of the first die or one of the plurality of dies to a heat spreader.

In Example 45, the subject matter of Example 44 optionally includes grinding a first end of at least a portion of the plurality of metal pillars.

In Example 46, the subject matter of Example 45 optionally includes attaching the heat spreader to the first end of the at least a portion of the plurality of metal pillars.

In Example 47, the subject matter of any one or more of Examples 44-46 optionally include attaching the heat spreader to the first of the plurality of metal pillars.

In Example 48, the subject matter of any one or more of Examples 44-47 optionally include forming at least one metal plate in between at least two of the plurality of dies during stacking the plurality of dies.

In Example 49, the subject matter of Example 48 optionally includes forming a conformal layer in between at least two of the plurality of dies during stacking the plurality of dies.

In Example 50, the subject matter of any one or more of Examples 44-49 optionally include wherein forming the plurality of metal pillars comprises forming a first end of at least one of the plurality of metal pillars proximate a hotspot of a respective one of the plurality of dies or the first die.

In Example 51, the microelectronics packages, systems, apparatuses, or method of any one or any combination of Examples 1-50 can optionally be configured such that all elements or options recited are available to use or select from.

The above detailed description includes references to the accompanying drawings, which form a part of the detailed description. The drawings show, by way of illustration, specific embodiments in which the invention can be practiced. These embodiments are also referred to herein as “examples.” Such examples can include elements in addition to those shown or described. However, the present inventors also contemplate examples in which only those elements shown or described are provided. Moreover, the present inventors also contemplate examples using any combination or permutation of those elements shown or described (or one or more aspects thereof), either with respect to a particular example (or one or more aspects thereof), or with respect to other examples (or one or more aspects thereof) shown or described herein.

In the event of inconsistent usages between this document and any documents so incorporated by reference, the usage in this document controls.

In this document, the terms “a” or “an” are used, as is common in patent documents, to include one or more than one, independent of any other instances or usages of “at least one” or “one or more.” In this document, the term “or” is used to refer to a nonexclusive or, such that “A or B” includes “A but not B,” “B but not A,” and “A and B,” unless otherwise indicated. In this document, the terms “including” and “in which” are used as the plain-English equivalents of the respective terms “comprising” and “wherein.” Also, in the following claims, the terms “including” and “comprising” are open-ended, that is, a system, device, article, composition, formulation, or process that includes elements in addition to those listed after such a term in a claim are still deemed to fall within the scope of that claim. Moreover, in the following claims, the terms “first,” “second,” and “third,” etc. are used merely as labels, and are not intended to impose numerical requirements on their objects.

The above description is intended to be illustrative, and not restrictive. For example, the above-described examples (or one or more aspects thereof) may be used in combination with each other. Other embodiments can be used, such as by one of ordinary skill in the art upon reviewing the above description. The Abstract is provided to comply with 37 C.F.R. § 1.72(b), to allow the reader to quickly ascertain the nature of the technical disclosure. It is submitted with the understanding that it will not be used to interpret or limit the scope or meaning of the claims. Also, in the above Detailed Description, various features may be grouped together to streamline the disclosure. This should not be interpreted as intending that an unclaimed disclosed feature is essential to any claim. Rather, inventive subject matter may lie in less than all features of a particular disclosed embodiment. Thus, the following claims are hereby incorporated into the Detailed Description as examples or embodiments, with each claim standing on its own as a separate embodiment, and it is contemplated that such embodiments can be combined with each other in various combinations or permutations. The scope of the invention should be determined with reference to the appended claims, along with the full scope of equivalents to which such claims are entitled.

What is claimed is:

1. A microelectronics package comprising:
a substrate;
a first die connected to the substrate;
a second die located above the first die;
a third die located above the first die;
a heat spreader located above the second and third dies; and
a first metal pillar extending from a first surface of the first die to the heat spreader, the first metal pillar located in between the second and third dies.

2. The microelectronics package of claim 1, further comprising a second metal pillar extending from the second die to the heat spreader.

3. The microelectronics package of claim 2, further comprising a third metal pillar extending from the third die to the heat spreader.

4. The microelectronics package of claim 1, further comprising a metal plate attached to a surface of the first die, the first metal pillar thermally connecting the metal plate to the heat spreader.

5. The microelectronics package of claim 4, further comprising a conformal metal layer on at least one of the first, second, or third die, the conformal metal layer located between first metal pillar and the at least one of the first, second, or third die.

6. The microelectronics package of claim 1, further comprising a thermal interface material located in between the first metal pillar and at least one of the first and second dies.

7. The microelectronics package of claim 4, wherein the metal plate defines a plurality of through holes sized to allow one or more bumps to pass though the metal plate.

8. The microelectronics package of claim 1, wherein the first metal pillar defines a second conductive pathway from at least one of the second and third dies to the heat spreader.

9. The microelectronics package of claim 1, wherein the first metal pillar comprising copper.

10. The microelectronics package of claim 1, wherein the first metal pillar does not form an electrical pathway through the microelectronics package.

11. A microelectronics package comprising:
a substrate;
a plurality of dies stacked on the substrate;
a heat spreader located proximate at least a portion of the plurality of dies; and
a plurality of metal pillars, respective ones of the plurality of metal pillars extending from at least one of the plurality dies to the heat spreader, each of the plurality of metal pillars defining a respective pathway from at least one of the plurality of dies to the heat spreader.

12. The microelectronics package of claim 11, wherein at least one of the plurality of metal pillars connects at least two of the plurality of dies to the heat spreader.

13. The microelectronics package of claim 11, further comprising a plurality of metal plates, each of the plurality of metal plates attached to a surface of at least one of the plurality of dies, at least a portion of the metal pillars thermally connecting the plurality of metal plates to the heat spreader.

14. The microelectronics package of claim 13, further comprising at least one sputtered conformal layer that is at least one of a sputter and plated metal layer.

15. The microelectronics package of claim 11, further comprising a thermal interface material located in between the first metal pillar and at least one of the first and second dies.

16. The microelectronics package of claim 13, wherein each of the plurality of metal layer defines a plurality of through holes sized to allow one or more bumps and the first metal pillar to pass though the metal layer.

17. The microelectronics package of claim 11, wherein a first end of at least a portion of the plurality of metal pillars is located proximate a hotspot of a respective one of the plurality of dies.

18. The microelectronics package of claim 11, wherein the plurality of metal pillars does not form electrical pathways through the microelectronics package.

19. A method of manufacturing a microelectronics package, the method comprising:
forming a substrate layer having a substrate surface;
attaching a first die to the substrate surface;
stacking a plurality of dies to the first die; and
forming a plurality of metal pillars, each of the plurality of metal pillars thermally coupling at least one of the first die or one of the plurality of dies to a heat spreader.

20. The method of claim 19, further comprise grinding a first end of at least a portion of the plurality of metal pillars.

21. The method of claim 20, further comprising attaching the heat spreader to the first end of the at least a portion of the plurality of metal pillars.

22. The method of claim 19, further comprising attaching the heat spreader to the first of the plurality of metal pillars.

23. The method of claim 19, further comprising forming at least one metal plate in between at least two of the plurality of dies during stacking the plurality of dies.

24. The method of claim 23, further comprising forming a conformal layer in between at least two of the plurality of dies during stacking the plurality of dies.

25. The method of claim 19, wherein forming the plurality of metal pillars comprises forming a first end of at least one of the plurality of metal pillars proximate a hotspot of a respective one of the plurality of dies or the first die.
